(19) United States
(12) Patent Application Publication
(10) Pub. No.: US 2010/0035422 A1
(43) Pub. Date: Feb. 11, 2010

(54) METHODS FOR FORMING DOPED REGIONS IN A SEMICONDUCTOR MATERIAL

(75) Inventors: Roger Yu-Kwan Leung, San Jose, CA (US); De-Ling Zhou, Sunnyvale, CA (US); Wenya Fan, Campbell, CA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL, INC., Morristown, NJ (US)

(21) Appl. No.: 12/186,999

(22) Filed: Aug. 6, 2008

(51) Int. Cl. H01L 21/22

(52) U.S. Cl. 438/558; 257/E21.149

(57) ABSTRACT

Methods for forming doped regions in a semiconductor material that minimize or eliminate vapor diffusion of a dopant element and/or dopant from a deposited dopant and/or into a semiconductor material and methods for fabricating semiconductor devices that minimize or eliminate vapor diffusion of a dopant element and/or dopant from a deposited dopant and/or into a semiconductor material are provided. In one exemplary embodiment, a method for forming doped regions in a semiconductor material comprises depositing a conductivity-determining type dopant comprising a dopant element overlying a first portion of the semiconductor material. A diffusion barrier material is applied such that it overlies a second portion of the semiconductor material. The dopant element of the conductivity-determining type dopant is diffused into the first portion of the semiconductor material.

### FIELD OF THE INVENTION

The present invention generally relates to methods for fabricating semiconductor devices, and more particularly relates to methods for forming doped regions in a semiconductor material by minimizing vapor diffusion of patterned conductivity-determining type dopant materials.

### BACKGROUND OF THE INVENTION

Doping of semiconductor materials with conductivity-determining type impurities, such as n-type and p-type dopant elements, is used in a variety of applications that require modification of the electrical characteristics of the semiconductor substrates. Typically, elements such as phosphorous, arsenic, or antimony are used to fabricate n-type semiconductor materials, while boron is used to fabricate p-type semiconductor materials.

In some applications, such as, for example, solar cells, it is desirable to dope the semiconductor substrate in a pattern having very fine lines or features. The most common type of solar cell is configured as a large-area p-n junction made from silicon. In one type of such solar cell 10, illustrated in FIG. 1, a silicon wafer 12 having a light-receiving front side 14 and a back side 16 is provided with a basic doping, wherein the basic doping can be of the n-type or of the p-type. The silicon wafer is further doped at one side (in FIG. 1, front side 14) with a dopant of opposite charge of the basic doping, thus forming a p-n junction 18 within the silicon wafer. Photons from light are absorbed by the light-receiving side 14 of the silicon to the p-n junction where charge carriers, i.e., electrons and holes, are separated and conducted to a conductive contact, thus generating electricity. The solar cell is usually provided with metallic contacts 20, 22 on the light-receiving front side as well as on the back side, respectively, to carry away the electric current produced by the solar cell. The metal contacts on the light-receiving front side pose a challenge in regard to the degree of efficiency of the solar cell because the metal covering of the front side surface causes shading of the effective area of the solar cell. Although it may be desirable to reduce the metal contacts as much as possible so as to reduce the shading, a metal covering of approximately 5% remains unavoidable since the metallization has to occur in a manner that keeps the electrical losses small. In addition, contact resistance within the silicon adjacent to the electrical contact increases significantly as the size of the metal contact decreases. However, a reduction of the contact resistance is possible by doping the silicon in narrow areas 24 directly adjacent to the metal contacts on the light-receiving front side 14.

FIG. 2 illustrates another common type of solar cell 30. Solar cell 30 also has a silicon wafer 12 having a light-receiving front side 14 and a back side 16 and is provided with a basic doping, wherein the basic doping can be of the n-type or of the p-type. The light-receiving front side 14 has a rough or textured surface that serves as a light trap, preventing absorbed light from being reflected back out of the solar cell. The metal contacts 32 of the solar cell are formed on the back side 16 of the wafer. The silicon wafer is doped at the backside relative to the metal contacts, thus forming p-n junctions 18 within the silicon wafer. Solar cell 30 has an advantage over solar cell 10 in that all of the metal contacts of the cell are on the back side 16. In this regard, there is no shading of the effective area of the solar cell. However, for all contacts to be formed on the back side 16, the doped regions adjacent to the contacts have to be quite narrow.

As noted above, both solar cell 10 and solar cell 30 benefit from the use of very fine, narrow doped regions formed within a semiconductor substrate. However, present-day methods of doping, such as photolithography, present significant drawbacks. For example, while doping of substrates in fine-lined patterns is possible with photolithography, photolithography is an expensive and time consuming process. Printing methods, such as screen or roller printing, also present challenges. For example, one challenge with such methods, which use liquid dopants, is the vapor diffusion of the dopant elements of the dopant or the dopant itself into the semiconductor material. As illustrated in FIG. 5, after deposition of a liquid conductivity-determining type dopant 100 onto a semiconductor material 102, dopant elements and/or the dopant itself may vaporize from the deposited dopant 100 (indicated by arrows 108) on the penned areas 104, that is, the areas upon which the dopant is deposited, onto and into unpenned regions 106 of the semiconductor material 102 (indicated by arrows 110) before or during the high temperature anneal. Significant diffusion of the dopant elements and/or the dopant before or during annealing at the proper annealing temperature may substantially adversely affect the electrical properties of devices comprising the resulting doped regions. Significant diffusion of the dopant elements and/or dopant by vapor transport before or during the annealing process should be minimized or eliminated so as to achieve localized doping without significantly changing the desired dopant distribution within the penned and unpenned areas of the semiconductor material.

Accordingly, it is desirable to provide methods for forming doped regions in a semiconductor material that minimize or eliminate vapor diffusion of dopant elements and/or dopant from a deposited dopant and/or into a semiconductor material. In addition, it is desirable to provide methods for fabricating semiconductor devices that minimize or eliminate vapor diffusion of dopant elements and/or dopant from a deposited dopant and/or into a semiconductor material. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Methods for forming doped regions in a semiconductor material that minimize or eliminate vapor diffusion of a dopant element and/or dopant from a deposited dopant and/or into a semiconductor material and methods for fabricating semiconductor devices that minimize or eliminate vapor diffusion of a dopant element and/or dopant from a deposited dopant and/or into a semiconductor material are provided. In one exemplary embodiment, a method for forming doped regions in a semiconductor material comprises depositing a conductivity-determining type dopant comprising a dopant element overlying a first portion of the semiconductor material. A diffusion barrier material is applied such that it overlies a second portion of the semiconductor material. The dopant element of the conductivity-determining type dopant is diffused into the first portion of the semiconductor material.

A method for fabricating a semiconductor device is provided in accordance with another exemplary embodiment. The method comprises providing a semiconductor material and printing a conductivity-determining type dopant overlying a first portion of the semiconductor material in a predetermined pattern. A diffusion barrier material is applied such that it overlies a second portion of the semiconductor material. The semiconductor material is heated after the steps of printing the conductivity-determining type dopant and applying the diffusion barrier material.

### BRIEF DESCRIPTION OF THE DRAWINGS

The present invention will hereinafter be described in conjunction with the following drawing figures, wherein like numerals denote like elements, and wherein:

FIG. 1 is a schematic illustration of a conventional solar cell with a light-side contact and a back side contact;

FIG. 2 is a schematic illustration of another conventional solar cell with back side contacts;

FIG. 3 is a cross-sectional view of an inkjet printer mechanism distributing ink on a substrate;

FIG. 4 is a cross-sectional view of an aerosol jet printer mechanism distributing ink on a substrate;

FIG. 5 is a schematic cross-sectional diagram illustrating out-diffusion and in-diffusion of dopant ions or dopant material from a dopant disposed on a semiconductor material;

FIG. 6 is a flow chart of a method for fabricating a semiconductor device in accordance with an exemplary embodiment of the present invention;

FIG. 7 is a schematic cross-sectional view of a diffusion barrier material overlying a dopant disposed overlying a semiconductor material with a portion of the semiconductor material exposed, in accordance with an exemplary embodiment of the present invention;

FIG. 8 is a schematic cross-sectional view of a diffusion barrier material overlying a semiconductor material and a dopant disposed overlying the semiconductor material, in accordance with an exemplary embodiment of the present invention;

FIG. 9 is a schematic cross-sectional view of a diffusion barrier material overlying a first portion of a semiconductor material and a dopant disposed overlying a substantially different second portion of the semiconductor material, in accordance with an exemplary embodiment of the present invention;

FIG. 10 is an illustration of a portion of a molecular structure of a silicate;

FIG. 11 is an illustration of a portion of a molecular structure of a siloxane;

FIG. 12 is an illustration of a portion of a molecular structure of an end-capped silicate; and

FIG. 13 is an illustration of a portion of a molecular structure of an end-capped siloxane.

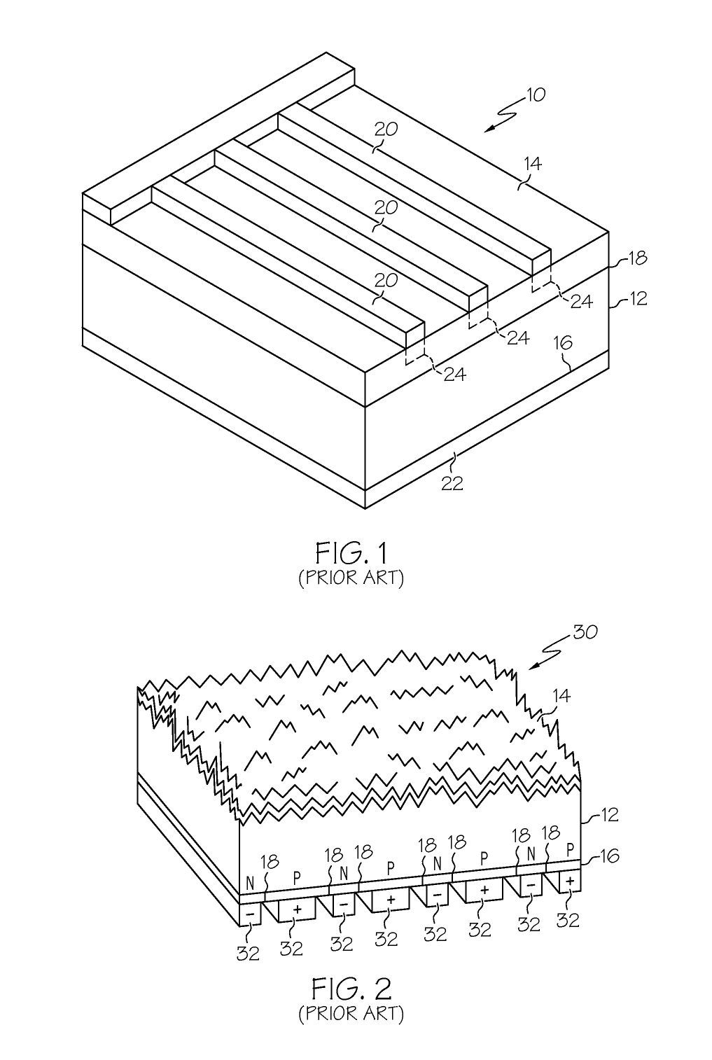

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Methods for forming doped regions in a semiconductor material that minimize or eliminate vapor diffusion of dopant elements and/or dopant out from a deposited dopant and/or into a semiconductor material and methods for fabricating semiconductor devices that minimize or eliminate vapor diffusion of dopant elements and/or dopant out from a deposited dopant and/or into a semiconductor material are provided herein. The methods utilize “application processes” that include both non-contact printing processes and contact printing processes.

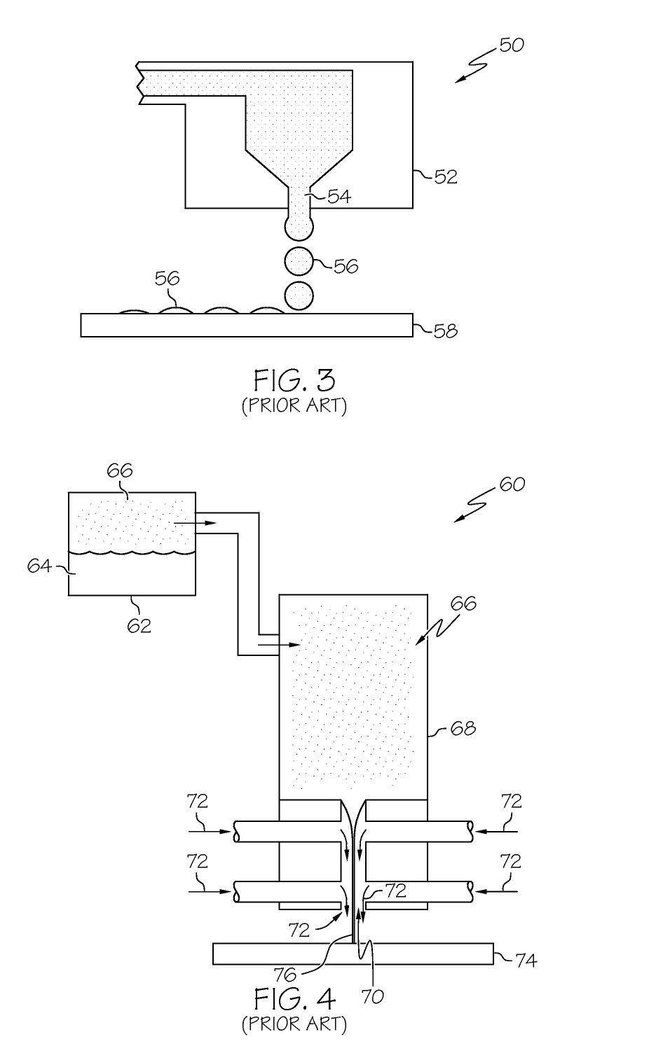

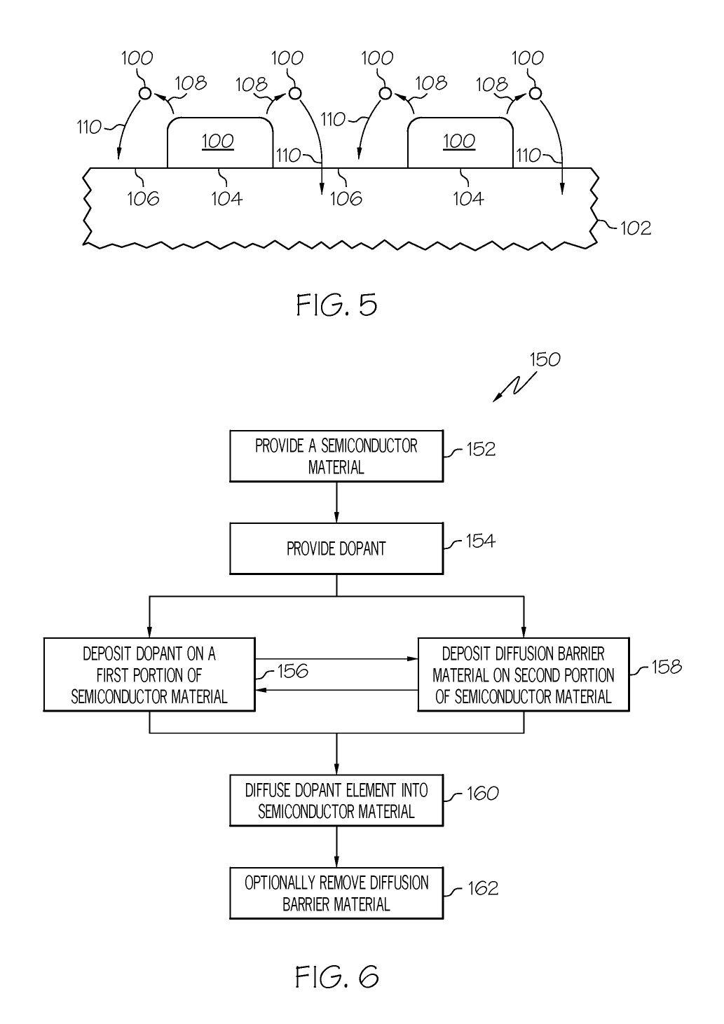

As used herein, the term “non-contact printing process” means a process for depositing a liquid conductivity-determining type dopant selectively on a semiconductor material in a predetermined patterned without the use of a mask, screen, or other such device. Examples of non-contact printing processes include but are not limited to “inkjet printing” and “aerosol jet printing.” Typically, the terms “inkjet printing,” an “inkjet printing process,” “aerosol jet printing,” and an “aerosol jet printing process” refer to a non-contact printing process whereby a liquid is projected from a nozzle directly onto a substrate to form a desired pattern. In an inkjet printing mechanism 50 of an inkjet printer, as illustrated in FIG. 3, a print head 52 has several tiny nozzles 54, also called jets. As a substrate 58 moves past the print head 52, or as the print head 52 moves past the substrate, the nozzles spray or “jet” ink 56 onto the substrate in tiny drops, forming images of a desired pattern. In an aerosol jet printing mechanism 60, illustrated in FIG. 4, a mist generator or nebulizer 62 atomizes a liquid 64. The atomized fluid 66 is aerodynamically focused using a flow guidance deposition head 68, which creates an annular flow of sheath gas, indicated by arrow 72, to collimate the atomized fluid 66. The co-axial flow exits the flow guidance head 68 through a nozzle 70 directed at the substrate 74 and focuses a stream 76 of the atomized material to as small as a tenth of the size of the nozzle orifice (typically 100 μm). Patterning is accomplished by attaching the substrate to a computer-controlled platen, or by translating the flow guidance head while the substrate position remains fixed.

Such non-contact printing processes are particularly attractive processes for fabricating doped regions in semiconductor materials for a variety of reasons. First, unlike screen printing or photolithography, only a dopant that is used to form the doped regions touches or contacts the surface of the semiconductor material upon which the dopant is applied. Thus, because the breaking of semiconductor materials could be minimized compared to other known processes, non-contact processes are suitable for a variety of semiconductor materials, including rigid and flexible semiconductor materials. In addition, such non-contact processes are additive processes, meaning that the dopant is applied to the semiconductor materials in the desired pattern. Thus, steps for removing material after the printing process, such as is required in photolithography, are eliminated. Further, because such non-contact processes are additive processes, they are suitable for semiconductor materials having smooth, rough, or textured surfaces. Non-contact processes also permit the formation of very fine features on semiconductor materials. In one embodiment, features, such as, for example, lines, dots, rectangles, circles, or other geometric shapes, having at least one dimension of less than about 200 μm can be formed. In another exemplary embodiment, features having at least one dimension of less than about 100 μm can be formed. In a preferred embodiment, features having at least one dimension of less than about 20 μm can be formed. In addition, because non-contact processes involve digital computer printers that can be programmed with a selected pattern to be formed on a semiconductor material or that can be provided the pattern from a host computer, no new masks or screens need to be produced when a change in the pattern is desired. All of the above reasons make non-contact printing processes cost-efficient processes for fabricating doped regions in semiconductor materials, allowing for increased throughput compared to screen printing and photolithography.

However, while non-contact printing processes are preferred methods for forming doped regions in a semiconductor material in accordance with certain exemplary embodiments of the present invention, the invention is not so limited and, in other exemplary embodiments, the liquid dopants can be deposited using other application processes, such as screen printing and roller printing, that can achieve localized doping. Screen printing involves the use of a patterned screen or stencil that is disposed over a semiconductor material. Liquid dopant is placed on top of the screen and is forced through the screen to deposit on the semiconductor material in a pattern that corresponds to the pattern of the screen. Roller printing involves a roller upon which is engraved a pattern. A liquid dopant is applied to the engraved pattern of the roller, which is pressed against a semiconductor material and rolled across the semiconductor material, thereby transferring the liquid dopant to the semiconductor material according to the pattern on the roller.

One challenge with non-contact printing processes and other printing processes used for localized doping involves the minimizing or eliminating of vapor diffusion of the dopant elements and/or the dopant from the deposited liquid dopant and/or into the semiconductor material, as described above. Accordingly, in an exemplary embodiment, a method 150 for fabricating a semiconductor device by forming doped regions in a semiconductor material using a process that minimizes or eliminates vapor diffusion of dopant elements and/or dopant from a deposited dopant and/or into a semiconductor material is illustrated in FIG. 6. As used herein, “semiconductor device” includes any electronic device that comprises a semiconductor material in which doped regions are formed. As shown in FIG. 6, method 150 includes the step of providing a semiconductor material (step 152). As used herein, the term “semiconductor material” will be used to encompass monocrystalline silicon materials, including the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other semiconductor materials such as relatively pure and impurity-doped germanium, gallium arsenide, zinc oxide, and the like. The semiconductor material may be a semiconductor substrate or wafer or may comprise any semiconductor material layer overlying a semiconductor substrate or wafer. In this regard, the method 150 can be used to fabricate a variety semiconductor devices including, but not limited to, microelectronics, solar cells and other photovoltaic devices, displays, RFID components, microelectromechanical systems (MEMS) devices, optical devices such as microlenses, medical devices, and the like.

The method 150 further includes the step of providing a conductivity-determining type impurity dopant (hereinafter, a “dopant”) (step 154), which step may be performed before, during or after the step of providing the semiconductor material. In accordance with an exemplary embodiment of the present invention, the dopant comprises the appropriate conductivity-determining type impurity dopant element that is required for the doping. For example, for forming n-type doped regions, the dopant includes the elements phosphorous, arsenic, antimony, or combinations thereof, in an ionic state, as part of a compound, or as a combination of both. For forming p-type doped regions, the dopant comprises boron, in an ionic state, as part of a compound, or as a combination of both. The dopant may comprise any suitable liquid dopant comprising the impurity elements. One example of a suitable dopant includes a liquid dopant comprising impurity elements combined with a silicate carrier. The terms “silicate” and “silicate carrier” are used herein to encompass silicon- and oxygen-containing compounds including, but not limited to, silicates, including organosilicates, siloxanes, silsesquioxanes, and the like. In one exemplary embodiment, suitable silicate carriers include commercially available silicate carriers such as, for example, USG-50, 103AS, 203AS, T30 and T111, all available from Honeywell International of Morristown, N.J. In another exemplary embodiment, a silicate carrier may be formed by combining at least one hydrolysable silane with at least one hydrogen ion contributor to undergo hydrolysis and polycondensation in a sol-gel reaction to form the silicate carrier. The dopant also may comprise other components or additives such as liquid mediums, pH modifiers, solvents, viscosity modifiers, dispersants, surfactants, polymerization inhibitors, wetting agents, antifoaming agents, detergents and other surface-tension modifiers, flame retardants, pigments, plasticizers, thickeners, rheology modifiers, and mixtures thereof.

In one exemplary embodiment, the dopant then is applied overlying the semiconductor material using any suitable localized-doping application process such as an inkjet printing process, an aerosol jet printing process, a screen printing process, a roller printing process, or the like (step 156). As used herein, the term “overlying” encompasses the terms “on” and “over”. Accordingly, the dopant can be applied directly onto the semiconductor material or may be deposited over the semiconductor material such that one or more other materials are interposed between the dopant and the semiconductor material. Examples of materials that may be interposed between the dopant and the semiconductor material are those materials that do not obstruct diffusion of the dopant into the semiconductor material during annealing. Such materials include phosphosilicate glass or borosilicate glass that forms on a silicon material during formation of P-well regions or N-well regions therein. Typically such silicate glass materials are removed by deglazing before dopants are deposited on the silicon material; however, in various embodiments, it may be preferable to omit the deglazing process, thereby permitting the silicate glass to remain on the semiconductor material.

The dopant is applied overlying a first portion of the semiconductor material according to a pattern that is stored in or otherwise supplied to an inkjet printer or an aerosol jet printer or that is encompassed or reflected in a screen, roller, or other template. An example of inkjet printers suitable for use includes, but is not limited to, Dimatix Inkjet Printer Model DMP 2811 available from Fujifilm Dimatix, Inc. of Santa Clara, Calif. An example of an aerosol jet printer suitable for use includes, but is not limited to, an M3D Aerosol Jet Deposition System available from Optomec, Inc. of Albuquerque, N. Mex. Preferably, the dopant is applied to the semiconductor material at a temperature in the range of about 15° C. to about 80° C. in a humidity of about 20 to about 80%.

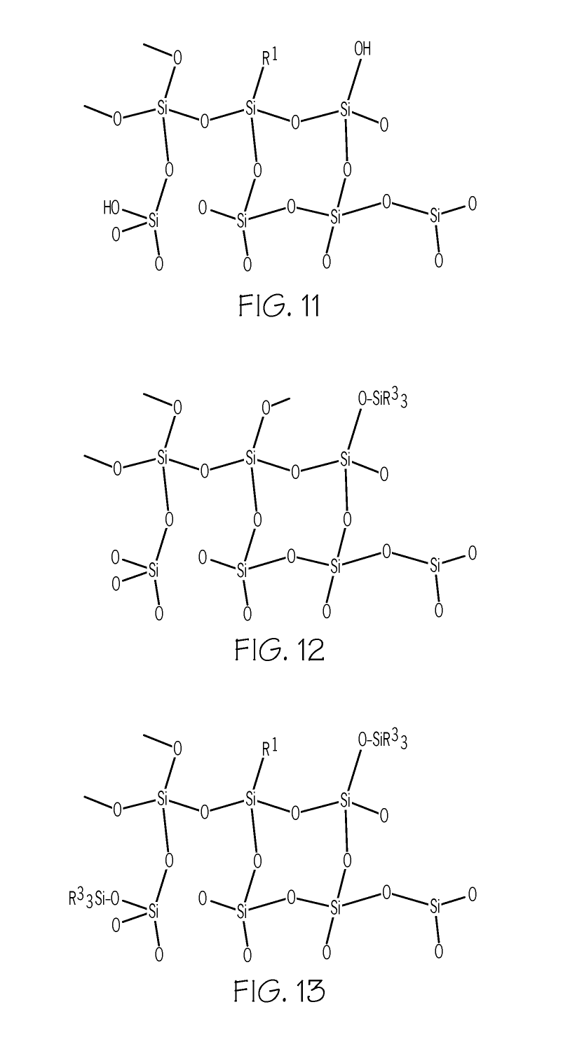

The method 150 further includes the step of depositing a diffusion barrier material overlying a second portion of the semiconductor material (step 158). The diffusion barrier material is comprised of any material that does not comprise the dopant element (that is, phosphorous, arsenic, antimony, combinations thereof, or boron, in an ionic state, as part of a compound, or as a combination of both) of the dopant and that is thermally stable up to temperatures of about 1100° C. so that it maintains its physical and/or chemical integrity during annealing of the dopant, as described in more detail below. The diffusion barrier material also is comprised of a material that can be selectively removed from the semiconductor material, that is, it can be removed from the semiconductor material using an etchant that does not etch or otherwise remove a portion of the semiconductor material. In addition, the diffusion barrier material is comprised of a material that can function as a barrier to vaporization or “out-diffusion” of dopant elements and/or dopant from the penned dopant and/or that can function as a barrier to diffusion of dopant elements and/or dopant into the semiconductor material (“in-diffusion”). Examples of diffusion barrier materials suitable for use include silicon oxides such as silicon dioxide (SiO₂), silicon nitrides such as silicon nitride (Si₃N₄), silicon carbides such as silicon carbide (SiC), silicates, titanium oxide (TiO₂), alumina (Al₂O₃), barium titanate (BaTiO₃), and the like. The term “silicate” is used herein to encompass silicon- and oxygen-containing compounds including, but not limited to, siloxanes, silsesquioxanes, silicates, including organosilicates, and the like. The backbone structure of a silicon-oxygen silicate is illustrated in FIG. 10 and the backbone structure of a silicon-oxygen siloxane is illustrated in FIG. 11. In one exemplary embodiment, suitable silicates include commercially available silicates such as, for example, USG-50, 103AS, 203AS, T30 and T111, all available from Honeywell International of Morristown, N.J.

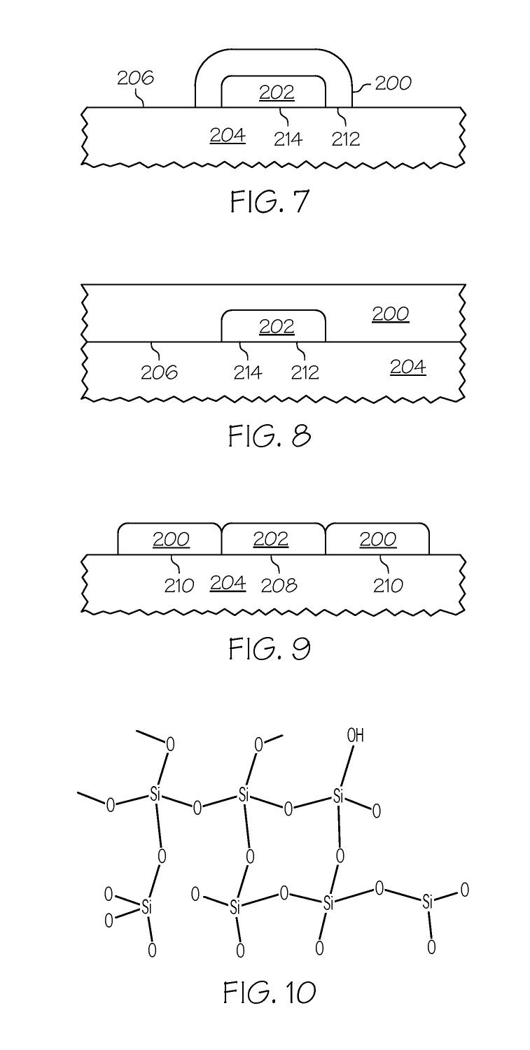

In one exemplary embodiment, as illustrated in FIG. 7, the diffusion barrier material 200 is deposited to overlie a second portion 212 of the semiconductor material 204 and at least partially overlie a dopant 202 overlying a first portion 214 of the semiconductor material 204. Thus, the second portion 212 may comprise a part of the first portion 214, the entire first portion, a part of the first portion and an additional portion of the semiconductor material, or the entire first portion and an additional portion of the semiconductor material. A third unpenned portion 206 of the semiconductor material remains exposed, that is, without overlying dopant 202 or diffusion barrier material 200.

In this regard, if the diffusion barrier material 200 comprises a silicate, it may be desirable for the silicate diffusion barrier material to be end-capped with a capping agent to minimize or eliminate clogging of printer nozzles and print heads due to gelation of the silicate. End-capping replaces the unreacted condensable (cross-linkable) group (e.g., —OH or —OR, where R is a methyl, ethyl, acetyl, or other alkyl group) of the silicate with a non-condensable (non-cross-linkable) alkylsilyl group or arylsilyl group (—SiR³₃), where R³ comprises one or more of the same or different alkyl and/or aryl groups, to become —OSiR³₃, thus reducing or, preferably, preventing gelation of the silicate. FIGS. 12 and 13 illustrate the silicate of FIG. 10 and the siloxane of FIG. 11, respectively, with end-capping. The total carbon content of the resulting end-capped dopant is in the range of about 0 to about 25 wt. %. The carbon content of the silicate includes carbon components from end-capping group R³ and from mid-chain group R¹. Suitable capping agents include acetoxytrimethylsilane, chlorotrimethylsilane, methoxytrimethylsilane, trimethylethoxysilane, triethylsilanol, triethylethoxysilane, and the like, and combinations thereof. The degree of end-capping is dependent on the silicate polymer size, the nozzle diameter, and the printing requirements. Preferably, the weight percent of the end-capping group of the end-capped silicate is about 0 to about 20% of the silicate. In a more preferred embodiment, the weight percent of the end-capping group of the end-capped silicate is no greater than about 5% of the silicate.

In another exemplary embodiment, as illustrated in FIG. 8, the diffusion barrier material 200 is deposited by spinning or spraying the material so that it overlies at least a portion of the dopant 202 and at least a portion of the unpenned regions 206 of the semiconductor wafer 204 in a continuous layer. In this regard, the second portion 212 comprises at least a part of first portion 214 and at least a portion of unpenned area 206. The diffusion barrier material can be spun onto semiconductor wafer 204 by spinning semiconductor wafer 204 at a spin speed of up to 1200 revolutions per minute or even higher while spraying the diffusion barrier material onto the spinning wafer at a desired fluid pressure. Spinning of the wafer causes the diffusion barrier material to spread outward substantially evenly across the wafer. The diffusion barrier material also can be sprayed onto an unmoving wafer at a desired fluid pressure at a position substantially at the center of the wafer. The fluid pressure causes the diffusion barrier material to spread radially and substantially evenly across the wafer.

In a further exemplary embodiment of the present invention, the dopant 202 is deposited by a printing process on a first portion 208 of the semiconductor material and the diffusion barrier material 200 then is deposited, also by a printing process, on a second portion 210 of the semiconductor material, as illustrated in FIG. 9. The second portion is substantially exclusive of the first portion but is sufficiently proximate to the first portion so that in-diffusion of vaporized dopant element and/or dopant from the first portion into the semiconductor material is substantially blocked by the diffusion barrier material. However, it will be appreciated that the invention is not so limited and that overlapping of the diffusion barrier material onto the dopant may occur.

In an alternative embodiment, instead of depositing the dopant before deposition of the diffusion barrier material, the diffusion barrier material 200 may be deposited on the second portion 210 of the semiconductor material before the dopant 202 is deposited on the first portion 208. Again, in a preferred embodiment, the first portion and the second portion are substantially mutually exclusive. However, it will be appreciated that the invention is not so limited and that overlapping of the dopant onto the diffusion barrier material may occur so long as the dimensions and/or concentrations of a resulting doped region are not substantially adversely affected.

Returning to FIG. 6, once the dopant and the diffusion barrier material are deposited overlying the semiconductor material, regardless of the method and the order of deposition, the dopant element is caused to diffuse from the dopant into the first region of the semiconductor material (step 160). The diffusion may be effected, for example, by subjecting the semiconductor material to a high-temperature thermal treatment or “anneal” to cause the dopant elements, in an ionic state or otherwise, of the dopant to diffuse into the semiconductor material, thus forming doped regions within the semiconductor material in a predetermined or desired manner. Annealing also has the effect of densifying the diffusion barrier material, thus forming a more effective barrier against out-diffusion and in-diffusion. The time duration and the temperature of the anneal is determined by such factors as the initial dopant concentration of the dopant, the thickness of the dopant deposit, the desired concentration of the resulting dopant region, and the depth to which the dopant is to diffuse. The anneal can be performed using any suitable heat-generating method, such as, for example, thermal annealing, infrared heating, laser heating, microwave heating, a combination thereof, and the like. In one exemplary embodiment of the present invention, the semiconductor material is placed inside an oven wherein the temperature is ramped up to a temperature in the range of about 850° C. to about 1100° C. and the substrate is baked at this temperature for about 2 to about 90 minutes. Annealing also may be carried out in an in-line furnace to increase throughput. The annealing atmosphere may contain 0 to 100% oxygen in an oxygen/nitrogen or oxygen/argon mixture. In a preferred embodiment, the substrate is subjected to an anneal temperature of about 1050° C. for about ten (10) minutes in an oxygen ambient.

In an optional embodiment of the present invention, after causing the dopant elements to diffuse from the dopant into the semiconductor material, the diffusion barrier material is removed from the semiconductor material (step 162). The diffusion barrier material may be removed using any suitable etchant and/or cleaner that is formulated to remove the diffusion barrier material without significant etching or removal of the semiconductor material. Deglazing of any dopant residue and fabrication of the semiconductor device then may continue using known materials and processes. In a preferred embodiment of the invention, the diffusion barrier material and any dopant residue are removed together in a single deglazing step.

The following are examples of methods for fabricating doped regions of semiconductor substrates. The methods illustrate the effectiveness of a diffusion barrier material in minimizing or eliminating in-diffusion and/or out-diffusion of dopant ions or dopant itself from a printed dopant. The examples are provided for illustration purposes only and are not meant to limit the various embodiments of the present invention in any way.

### EXAMPLE 1

Preparation of Boron Printable Dopant Ink: About 230 grams (gm) B30 borosilicate, available from Honeywell International, was mixed with 23.00 gm acetoxytrimethylsilane and left at room temperature for about three hours to form an end-capped boron silicate ink. About 190 gm solvent then was distilled from the end-capped boron silicate ink using a rotary evaporator while keeping the solution at a temperature below 23° C. The final weight of the end-capped boron silicate ink was 63.0 gm. 63.0 gm of the end-capped boron silicate ink was mixed with 63.0 gm ethanol. A final end-capped boron silicate ink was prepared by adding 2.10 gm boric acid to 126 gm of the mixture, stirring to dissolve the boric acid, and then filtering using a 0.2 μm nylon filter. The composition of the final end-capped boron silicate ink was 49.2 wt. % end-capped boron silicate ink, 49.2 weight percent (wt. % ethanol), and 1.6 wt. % boric acid.

Preparation of Non-Doped Silicate Diffusion Barrier Material: a First Solution, Solution 2A, was prepared by adding 100.49 gm of ethanol, 25.14 gm of tetraethylorthosilicate (TEOS), 21.53 gm of acetic anhydride and 6.76 gm of water to a reactor flask. The flask was fitted with a condenser and the solution in the flask was heated to reflux for 9 hours. A second solution, Solution 2B, was prepared by mixing 45.1 gm of ethanol, 36.8 gm glycerol and 8.1 gm of water. A third solution, Solution 2C, was prepared by mixing 45.9 gm of Solution 2A, 16.0 gm of Solution 2B and 23.5 gm of ethanol. A fourth solution, Solution 2D, was prepared by adding 6.00 gm of acetoxytrimethylsilane to 60.00 gm of Solution 2C. The solution was left at room temperature for 3 hours. A fifth solution, Solution 2E, was prepared by distilling 49.5 gm of volatile material from 66.0 gm of Solution 2D by rotary evaporation. The weight of the concentrate was 16.5 gm. 16.5 gm of ethanol was added to the concentrate to yield a final weight of 33.0 gm of non-doped silicate diffusion barrier material.

Printing: A Fujifilm Dimatix Inkjet Printer Model DMP 2811 having a 1 picoliter (pL) nozzle was used for printing on four 4-inch p-type polished wafers. Wafer 1 was set on a stage having a temperature of about 50° C. and the boron printable dopant ink was printed onto Wafer 1 using a drop spacing of 20 micrometers (μm). Printing continued until the ink was printed in the shape of a rectangle having a width of 2 centimeters (cm) and a length of 6 cm. After printing of the boron printable dopant ink, the diffusion barrier material was printed on the printed dopant ink using a drop spacing of 20 μm. The stage temperature for the second printing was also 50° C. While a second wafer, Wafer 2 remained a p-type wafer without any printing thereon, Wafer 3 was printed in the same manner as Wafer 1. The diffusion barrier material alone was printed onto a fourth wafer, Wafer 4, using the same conditions as described above to form a rectangle having a 2 cm width and a 6 cm length.

Annealing and Deglazing: Wafer 1 and Wafer 2 were placed in adjacent slots of a wafer boat of a tube furnace with a 4 mm gap between the wafers. Wafer 1 was positioned inward so that the printed rectangle of Wafer 1 was between Wafer 1 and Wafer 2. Wafer 3 and Wafer 4 were also placed next to each other with the printed rectangles facing each other. The wafers were then heated to 1060° C. in 2.5% oxygen/97.5% nitrogen atmosphere and held at 1060° C. for 30 minutes. The printed areas were marked by scribing and then immersed in 20:1 DHF solution for 10 minutes for deglazing. After deglazing, the wafers were clear of film and residue.

Sheet Resistance: The sheet resistances of Wafer 2 and Wafer 4 were measured to assess the effectiveness of the diffusion barrier material on Wafer 4 in minimizing or eliminating in-diffusion of dopant ions or dopant from the boron dopant ink printed on Wafers 1 and 3. Sheet resistance was measured using 4-point probe. The sheet resistance of the surface of Wafer 2 facing Wafer 1 was 4990 ohms-per-square (ohm/sq). The sheet resistance of Wafer 4 at the area formerly covered by the diffusion barrier material was 48900 ohm/sq. These results showed that the silicate diffusion barrier material increased the sheet resistance.

### EXAMPLE 2

B30 boron silicate spin-on dopant was spun onto a fifth 4-inch p-type wafer, Wafer 5, at a spin speed of 3000 rpm using a spin coater manufactured by Silicon Valley Group, San Jose, Calif. No bake was performed after spin coating.

A 2 cm×6 cm rectangle was printed on both sides of a sixth 4-inch p-type wafer, Wafer 6, using the barrier diffusion material described above in Example 1. The rectangles on each side were aligned in mirror fashion so that they covered approximately the same wafer area. The rest of the wafer was not covered by the barrier diffusion material. The rectangles were printed using a Fujifilm Dimatix Inkjet Printer Model DMP 2811 having a 1 pL nozzle and using a 20 μm drop spacing. The stage temperature was 50° C.

Wafer 5 and Wafer 6 were placed in adjacent slots of a wafer boat of a tube furnace with a 4 mm gap between the wafers. The dopant coating of Wafer 5 was positioned inward so that the boron silicate dopant faced Wafer 6. The wafers were then heated to 1060° C. in 2.5% oxygen/97.5% nitrogen atmosphere and held at 1060° C. for 30 minutes. The printed areas was marked by scribing and then the wafers were immersed in 20:1 DHF solution for 10 minutes for deglazing. After deglazing, the wafers were clear of film and residue. Sheet resistance was measured using 4-point probe and surface boron concentration was measured using secondary ion mass spectroscopy (SIMS). Sheet resistance and boron concentration of Wafer 6 were measured at two positions listed below:

a. The area of Wafer 6 formerly covered by the diffusion barrier material and facing Wafer 5 exhibited a sheet resistance of 2970 ohm/sq. Surface boron concentration was 1.0×10¹⁸ atoms/cubic centimeter (cc) with a junction depth of 0.8 μm.

b. The area of Wafer 6 not formerly covered by the diffusion barrier material and facing Wafer 5 exhibited a sheet resistance of 272 ohm/sq. Surface boron concentration was 1.3×10¹⁹ atoms/cc with a junction depth of 1.1 μm. Thus, the diffusion barrier material increased the sheet resistance of the underlying area of Wafer 6 and minimized the amount of boron “in-diffusion” into the covered area.

### EXAMPLE 3

An array of lines 1.15 mm wide and 5 cm long was printed onto a 5-inch textured multicrystalline p-type wafer using the boron printable dopant ink from Example 1. The array comprised more than 20 lines. The lines were printed using a Fujifilm Dimatix Inkjet Printer Model DMP 2811 having a 1 μL nozzle and using a 20 μm drop spacing. The stage temperature was 50° C. The spacing between the lines after printing was measured at 0.35 mm. After printing, the stage temperature was allowed to cool to room temperature. The diffusion barrier material described above in Example 1 then was printed using the same line pattern as used to print the boron dopant ink. The diffusion barrier material lines were printed on the boron dopant ink lines using a 15 μm drop spacing. After the second printing, the diffusion barrier material line pattern was checked under microscope and was shown to align within 10 μm of the boron dopant ink line pattern. The wafer was then heated to 1060° C. in 2.5% oxygen/97.5% nitrogen atmosphere and held at 1060° C. for 30 minutes. Without deglazing, the boron concentrations of the printed lines and of the gaps between the lines were measured by SIMS. The boron concentration of a printed line at the wafer surface was measured to be 3×10¹⁰ atoms/cc with a 1.3 μm junction depth. In contrast, the boron concentration at the wafer surface between two lines was 7×10¹⁷ atoms/cc with a 0.6 μm junction depth. Thus, the resulting boron concentration between the two lines when annealing is performed with the diffusion barrier material overlying the dopant ink was substantially similar to the boron concentration of the area of Wafer 6, described above, that was covered by the diffusion barrier material during annealing.

Accordingly, methods for forming doped regions in a semiconductor material that minimize or eliminate vapor diffusion of dopant elements and/or dopant from a deposited dopant and/or into a semiconductor material and methods for fabricating semiconductor devices that minimize or eliminate vapor diffusion of dopant elements and/or dopant from a deposited dopant and/or into a semiconductor material have been provided. The methods include the use of a diffusion barrier material that functions as a barrier to vaporization or “out-diffusion” of dopant elements and/or dopant material from a dopant and/or functions as a barrier to “in-diffusion” of vaporized dopant elements and/or dopant material into the semiconductor material. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for forming doped regions in a semiconductor material, the method comprising the steps of:
depositing a conductivity-determining type dopant comprising a dopant element overlying a first portion of the semiconductor material;
applying a diffusion barrier material such that it overlies a second portion of the semiconductor material; and
diffusing the dopant element of the conductivity-determining type dopant into the first portion of the semiconductor material.

2. The method of claim 1, further comprising the step of removing the diffusion barrier material after the step of diffusing.

3. The method of claim 1, wherein the step of applying comprises the step of applying the diffusion barrier material such that it at least partially overlies the conductivity-determining type dopant, and wherein an unpenned portion of the semiconductor material remains exposed.

4. The method of claim 1, wherein the step of applying comprises the step of applying the diffusion barrier material such that it at least partially overlies the conductivity-determining type dopant and an unpenned portion of the semiconductor material.

5. The method of claim 1, wherein the step of applying and the step of depositing are performed so that the first and the second portions are substantially mutually exclusive.

6. The method of claim 5, wherein the step of applying is performed before the step of depositing.

7. The method of claim 1, wherein the step of applying comprises applying using an inkjet printer.

8. The method of claim 1, wherein the step of applying comprises applying using an aerosol jet printer.

9. The method of claim 1, wherein the step of applying comprises applying a material selected from the group consisting of silicon oxides, silicon nitrides, silicon carbides, siloxanes, silsesquioxanes, silicates, including organosilicates, titanium oxide, alumina, and barium titanate.

10. The method of claim 9, wherein the step of applying comprises applying a material selected from the group consisting of end-capped siloxanes, end-capped silsesquioxanes, and end-capped silicates, including end-capped organosilicates.

11. The method of claim 1, wherein the step of depositing comprises depositing a conductivity-determining type dopant comprising phosphorous or boron, in an ionic state, as a compound, or as a combination of both.

12. The method of claim 1, wherein the step of diffusing is performed using thermal annealing, infrared heating, laser heating, microwave heating, or a combination thereof.

13. A method for fabricating a semiconductor device, the method comprising the steps of:
providing a semiconductor material;
printing a conductivity-determining type dopant overlying a first portion of the semiconductor material in a predetermined pattern;
applying a diffusion barrier material such that it overlies a second portion of the semiconductor material; and
heating the semiconductor material after the steps of printing and applying.

14. The method of claim 13, wherein the step of applying comprises the step of applying the diffusion barrier material such that it at least partially overlies the conductivity-determining type dopant and the first portion, and wherein an unpenned portion of the semiconductor material remains exposed.

15. The method of claim 13, wherein the step of applying comprises the step of spinning or spraying the diffusion barrier material onto the semiconductor material such that it overlies at least the second portion of the semiconductor material.

16. The method of claim 13, wherein the first portion and the second portion are substantially mutually exclusive.

17. The method of claim 16, wherein the step of applying is performed before the step of depositing.

18. The method of claim 13, wherein the step of printing comprises printing using an inkjet printer.

19. The method of claim 13, wherein the step of printing comprises printing using an aerosol jet printer.

20. The method of claim 13, wherein the step of applying comprises applying a material selected from the group consisting of oxides, nitrides, carbides, siloxanes, silsesquioxanes, silicates, including organosilicates, titanium oxide, alumina, and barium titanate.
